(19) United States
(12) Patent Application Publication
(10) Pub. No.: US 2009/0289349 A1
(43) Pub. Date: Nov. 26, 2009

(54) HERMETIC SEALING OF MICRO DEVICES

(75) Inventors: Vlad Novotny, Los Gatos, CA (US); Gabriel Matus, Santa Clara, CA (US)

Correspondence Address: FISH & RICHARDSON P.C., PO BOX 1022, MINNEAPOLIS, MN, 55440-1022, US

(73) Assignee: SPATIAL PHOTONICS, INC., Sunnyvale, CA (US)

(21) Appl. No.: 12/124,962

(22) Filed: May 21, 2008

(51) Int. Cl. H01L 23/48; H01L 21/66

(52) U.S. Cl. 257/698; 438/15; 257/E21.531; 257/E23.01

(57) ABSTRACT

An encapsulated device includes a micro device on a substrate, a micro chamber that encapsulates the micro device on the substrate; and a layer of hermetic-sealing material that provides at least some degree of hermeticity on one or more outer surfaces of the micro chamber to at least partially hermetically seal the micro device in the micro chamber.

### BACKGROUND

The present invention relates to the packaging of micro-electro-mechanical systems (hereinafter call “MEMS” or micro devices.

Multiple micro devices are commonly fabricated on a semiconductor wafer. The micro devices are subsequently packaged and separated into individual dies. Many types of micro devices may malfunction when they are exposed to water vapor or other gases and liquids. Therefore micro devices must be in a sealed environment to ensure a long operating life. It is therefore desirable to have an effective and efficient hermetic sealing process for multiple micro devices on a wafer and on individual dies.

### SUMMARY

In one general aspect, the present invention relates to encapsulated devices that include a plurality of micro devices on a substrate, a micro chamber that encapsulates the micro devices on the substrate; and a layer of inorganic sealing material that provides at least some degree of hermeticity on one or more outer surfaces of the micro chamber to seal each micro device in the micro chamber. In a preferred embodiment, the layer is conformal and fully hermetic.

In another general aspect, the present invention relates to a method for at least partial hermetic sealing of a plurality of micro devices. The method includes constructing non-hermetic micro chambers to encapsulate the plurality of micro devices on a substrate and depositing a layer of inorganic sealing material on one or more outer surfaces of the micro chamber to at least partially hermetically seal each micro device within the micro chamber.

Implementations of the system may include one or more of the following features. The layer of hermetic-sealing material can be conformally and isotropically or anisotropically deposited using a technique selected from the group consisting of atomic layer deposition (ALD), chemical vapor deposition (CVD), plasma enhanced CVD (PECVD), physical vapor deposition (PVD) and electroplating. The layer of hermetic-sealing material can have a thickness smaller than 5 microns. The layer of hermetic-sealing material can have a thickness in a range between about 1 nanometer and about 20 nanometers, preferably in a range between about 3 nanometers and about 10 nanometers. The hermetic-sealing material can include a material selected from the group consisting of Al₂O₃, SiO₂, TiO₂, Si₃N₄, SiO₂, Ni, Au, Cu, Pf, Ag, Sn, and Sb. The micro chamber can include an interposer plate bonded to an upper surface of the substrate or to the bottom surface of the encapsulation cover. The interposer plate can include an opening in which a micro device is positioned after the interposer plate is bonded to the upper surface of the substrate, and an encapsulation cover bonded to the interposer plate. An anti-stiction material and getter for water and other materials may be applied to the micro device before the encapsulation cover is bonded. The interposer plate and the encapsulation cover form the micro chamber to encapsulate the micro device. The encapsulation cover can be made of a transparent material. The interposer plate can be bonded to the substrate and the encapsulation cover can be bonded to the interposer plate by an organic adhesive. The substrate can include an electrical terminals on its upper surface in the vicinity of the micro device. The electrical terminals can receive an electrical signal to control to the micro device. Each device may be electrically tested, either before the encapsulation, after the encapsulation (through the electrical terminals) or both.

Various implementations of the methods and devices described may include one or more of the following advantages. The packaging system and method of the invention can provide more reliable hermetic sealing for micro devices than some conventional hermetic sealing techniques. The system and methods thus can assure proper operation of the micro devices by shielding them from water vapor and other hazardous gases. The system and methods can hermetically seal many micro devices on a wafer at high throughput. The system and methods are also simpler than some conventional hermetic sealing approaches. Another advantage is that hermetical sealing can be applied to micro devices at a low temperature that does not adversely affect the electric circuitry (such as CMOS or MEMS devices) that cannot tolerate high temperatures.

Although the invention has been particularly shown and described with reference to multiple embodiments, it will be understood by persons skilled in the relevant art that various changes in form and details can be made without departing from the spirit and scope of the invention.

### DESCRIPTION OF DRAWINGS

The following drawings, which are incorporated in and form a part of the specification, illustrate embodiments of the present invention and, together with the description, serve to explain the principles, devices and methods described herein.

FIG. 1 is a top view of a substrate having a plurality of micro devices each associated with electrodes in its vicinity.

FIG. 2A is a schematic top view of a micro device on the substrate.

FIG. 2B is a side view of a micro mirror compatible with a pixel cell in the micro device in FIG. 2A.

FIG. 3 is a cross-sectional view of the substrate along the line A-A in FIG. 1.

FIG. 4 is a plan view of an interposer device.

FIG. 5A is a cross-sectional view of the interposer device along the line B-B in FIG. 4.

FIG. 5B is a cross-sectional view of an alternative embodiment of the device shown in FIGS. 4 and 5A.

FIG. 6 is a cross-sectional view of the substrate and the interposer device along the line B-B in FIG. 4 after the interposer device is bonded to the top surface of the substrate.

FIG. 7 is a plan view of an encapsulation cover.

FIG. 8 is a cross-sectional view of the substrate having the plurality of micro devices encapsulated by the encapsulation cover and the interposer device.

FIG. 9 illustrates a hermetic sealing of the encapsulated micro device on the substrate in FIG. 8.

FIG. 10 illustrates additional non-hermetic sealing of the hermetically sealed chamber and the external electrodes after an encapsulated micro device wafer has been diced into separate die.

FIG. 11 is a flowchart for hermetic sealing the micro devices on a substrate.

### DETAILED DESCRIPTION

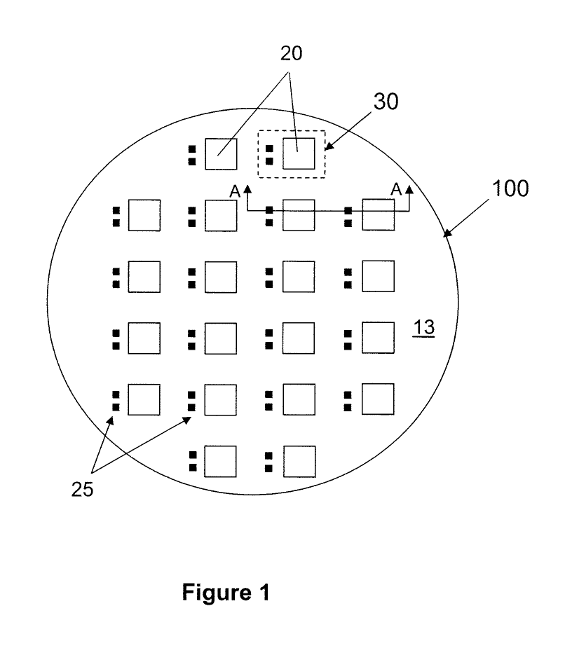

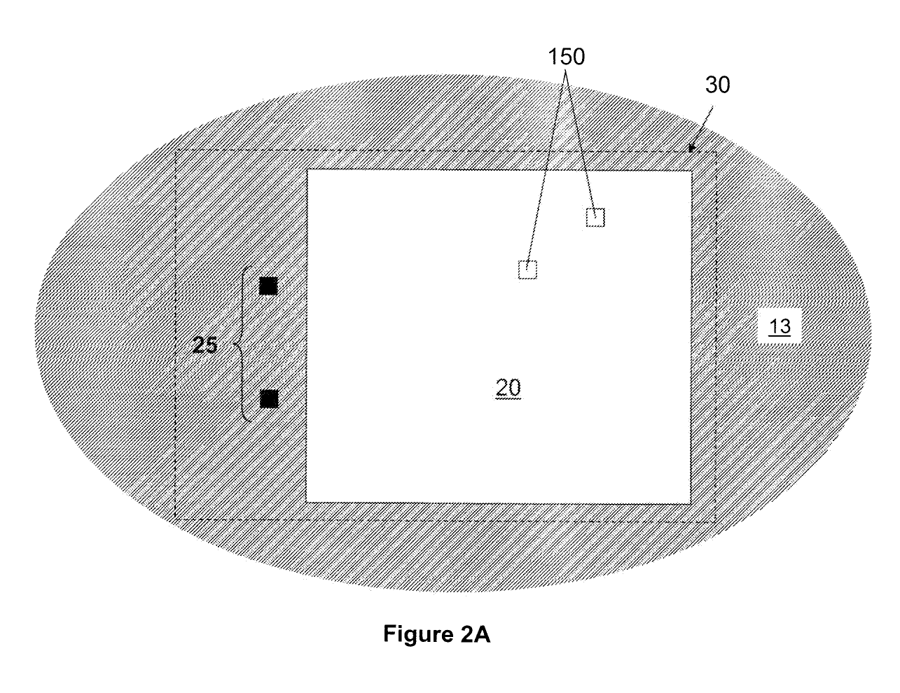

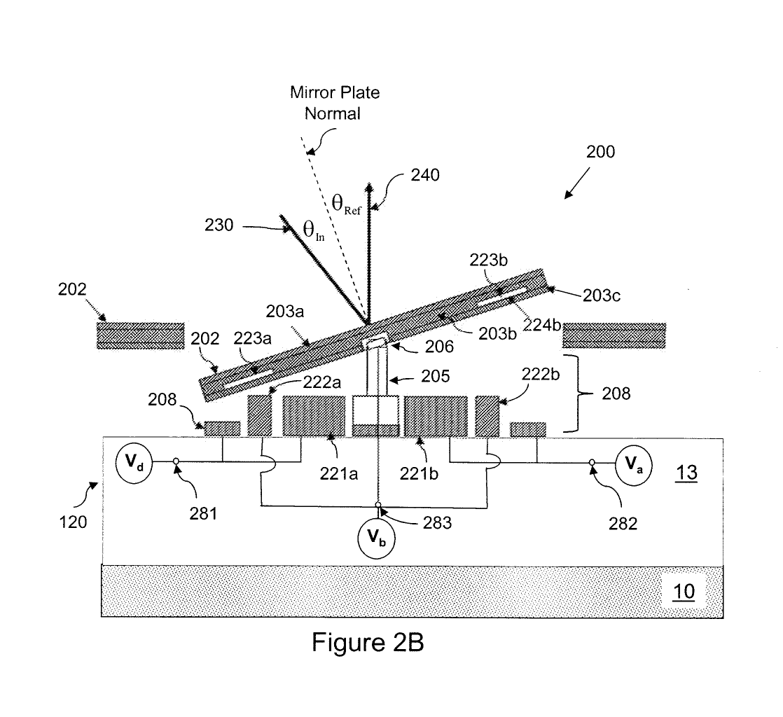

Referring to FIGS. 1-3, an assembly 100 includes a substrate 10, a control layer 13, a plurality of micro devices 20 over the control layer 13, and a plurality of input/output (I/O) terminals 25 for the micro devices 20. The micro devices 20 can be, for example, monolithically fabricated on the control layer 13 (FIG. 2A) or bonded as a wafer of devices 20, or as single chips onto the control layer 13. The substrate 10 can be any suitable support, such as a semiconductor wafer. The control layer 13 includes electronic circuits that can provide input signals from the I/O terminals 25 to the micro devices 20 and output signals from the micro devices 20 to the I/O terminals 25. The control layer 13 can for example be implemented by complimentary metal-oxide-semiconductor (CMOS) circuits.

The I/O terminals 25 are distributed in the vicinity of their associated micro devices 20 and can be connected to external electronic interconnects via wire bonding or flip chip bonding. The micro devices 20 can include microstructures that are capable of producing mechanical movements, electromagnetic signals, acoustic signals, or optical signals in response to input signals applied to the I/O terminals 25. For example, the micro devices 20 can include micromechanical electrical systems (MEMS) such as an array of tiltable micro mirrors, integrated circuits, micro sensors, micro actuators, or light emitting elements.

An exemplified micro device 20, shown in FIG. 2A, includes a plurality of pixel cells 150 distributed in an array (only two pixel cells 150 are indicated for the sake of simplicity). The micro device 20 is positioned in an area 30 (indicated by the dotted rectangle) on the control layer 13. A pixel cell 150 can include a micro mirror 200, as shown in FIG. 2B. Referring to FIG. 2B, the micro mirror 200 includes a mirror plate 202 that is tiltable around a hinge component 206. The hinge component 206 is supported by a post 205 that is connected to the control layer 13 in the assembly 100 (not shown in FIG. 2B). The mirror plate 202 can include two or more layers, such as a hinge layer 203c, a spacer layer 203b, and a reflective layer 203a. The reflective layer reflects an incident light beam from direction 230 to direction 240. A pair of electrodes 221a and 221b can be formed within a hinge support frame 208 on the control layer 13. A pair of mechanical stops 222a and 222b can also be formed on the hinge support frame 208 for stopping the tilt movement of the mirror plate 202 and defining precise tilt angles for the mirror plate 202. The hinge layer 203c can be made of an electrically conductive material. In some embodiments, the hinge layer 203c and the mechanical stops 222a and 222b are electrically connected to a common electrode 283. Alternatively, the electrodes 221a and 221b can be separately controlled

The control layer 13 includes an electric circuit that connects the electrodes 221a and 221b with the I/O terminals 25 (FIG. 2A). Electric signals can be applied from the I/O terminals 25 to the electrodes 221a and 221b to produce electric potential differences between the hinge layer 203c and the electrodes 221a or 221b. Applied voltage signals produce electrostatic torque that can tilt the mirror plate 202, such as away from an un-tilted direction (which may, for example, be parallel to the plane of the upper surface of the substrate 10). The tilting of the mirror plate 202 can distort the hinge (not shown). In turn, the hinge produces an elastic restoring force as the hinge is distorted. The elastic restoring force can pull the tilted mirror plate 202 back to the un-tilted position. The electrostatic torque can be sufficient to overcome the elastic restoring force to tilt the mirror plate 202 into contact with one of the mechanical stops 222a and 222b. The position of the mirror plate 202 in contact with the mechanical stops 222a or 222b can determine an “on” or an “off” position of the mirror plate and determine one of the directions 230 or 240 of the reflected light.

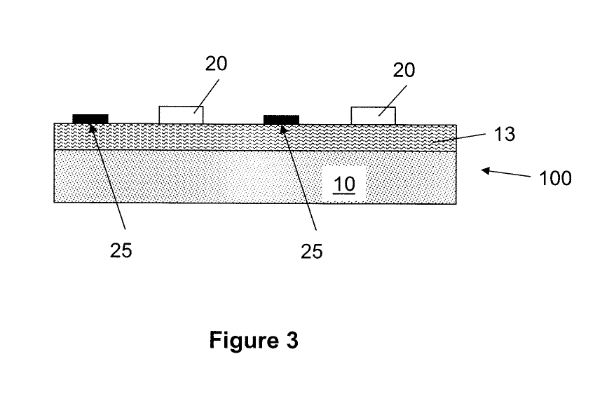

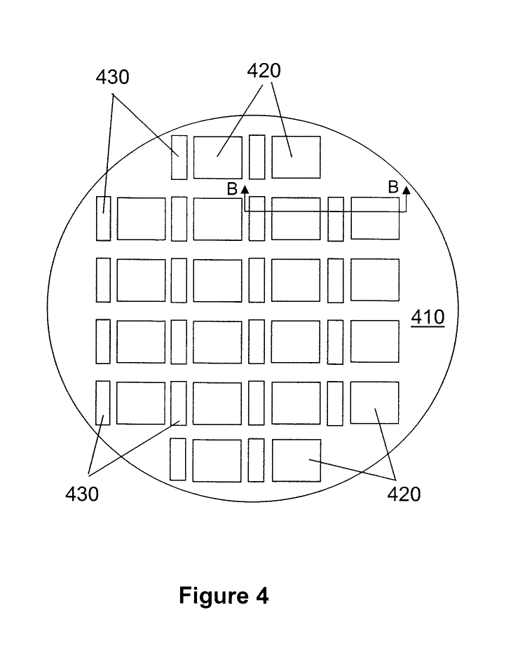

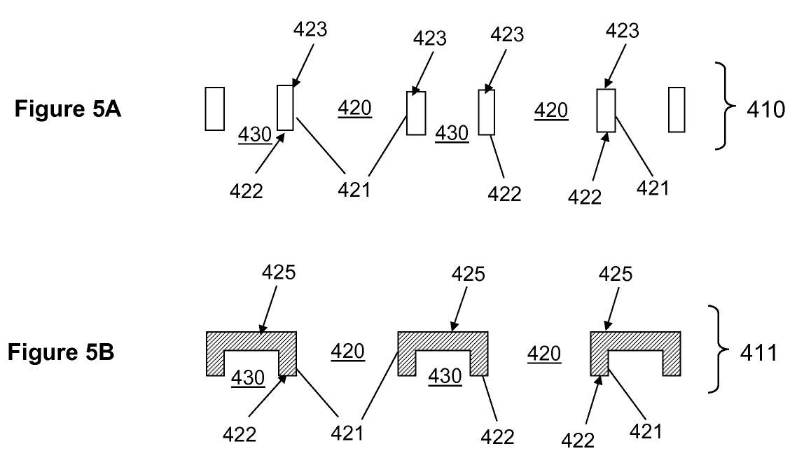

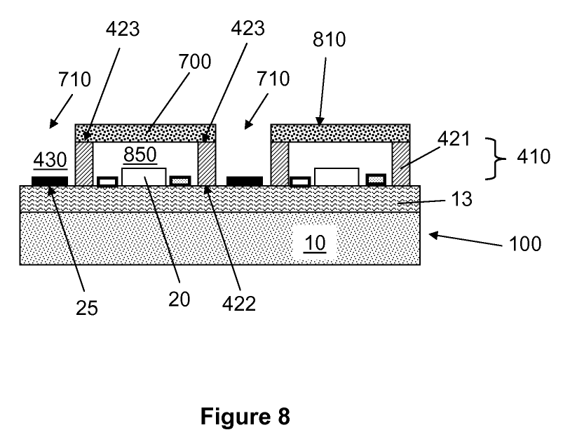

Referring to FIGS. 3, 4 and 5A, an interposer plate 410 that includes a plurality of device openings 420 and a plurality of terminal openings 430 is shown in FIGS. 4 and 5A. The device openings 420 and the terminal openings 430 are positioned such that they can be respectively registered to the micro devices 20 and the I/O terminals 25 when they are bonded to the control layer 13 as described below. The device openings 420 provide cavities in the chambers 850 (shown in FIG. 8). The terminal openings 430 provide access to the I/O terminals 25. In a cross-section, as shown in FIG. 5A, the interposer plate 410 comprises a plurality of spacer walls 421 separated by the device openings 420 and the terminal openings 430. The spacer walls 421 include bottom surfaces 422. Alternatively, in the embodiment shown in FIG. 5B, the interposer plate 411 has a cover 425 spanning the terminal openings 430. Such an interposer plate 411 with cover 425 is more mechanically rigid and less prone to breakage than the interposer plate 410 in FIGS. 4 and 5A.

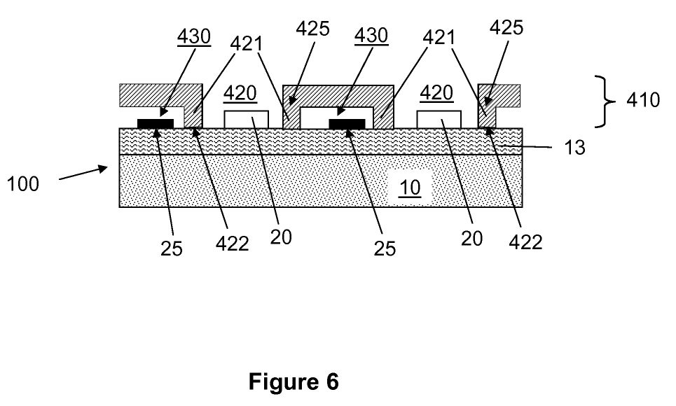

Referring to FIG. 6, the interposer plate 410 is next bonded to an upper surface of the control layer 13 in assembly 100. The bonding can for example be achieved by applying a sealing material such as an organic sealant (e.g., epoxy) to the base faces 422, followed by pressing the interposer plate 410 against the assembly 100. Conventionally, techniques such as soldering, glass frit, anodic bonding, and plasma-assisted bonding are used to produce hermetic bonding at the interface of a spacer wall and the upper surface of the substrate. In the present invention, however, hermeticity is not required at the bonding interface between the interposer plate 410 and the control layer 13 because of an additional hermetic sealing treatment that will be used, as described below. The non-hermetic bonding by organic sealant in this bonding procedure can be much less complicated and much less expensive than conventional hermetic bonding procedures.

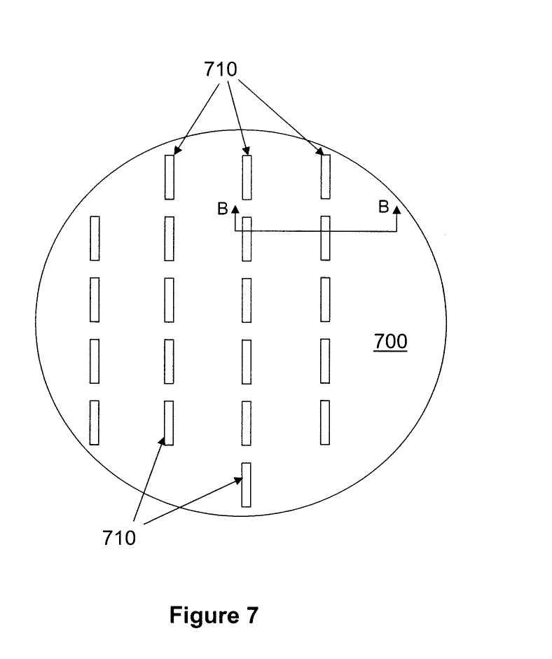

In one embodiment of the invention, an encapsulation cover 700, shown in FIGS. 7 and 8 includes a plurality of openings 710, although, if desired, these openings 710 may be created after bonding by dicing in order to enable wafer level test. The encapsulation cover 700 can be made of a transparent material such as glass to allow visual and microscopic examination of the micro devices 20 (shown in FIG. 8). When the micro device 20 is an opto-electrical device (such as the micro mirror 200 as shown in FIG. 2B), a transparent encapsulation cover 700 allows for optical communication with micro device 20. Antireflective layers can be coated on the upper and lower surfaces of the encapsulation cover 700 for reducing reflection and thus intensity losses in the light transmitted through the encapsulation cover 700. In addition, the inner surface 820 of encapsulation 700 can be coated with a non-transparent film. This film may be patterned to form a black aperture, such as around the periphery of inner surface 820 surrounding device 20. Preferably, there is a small space between where the periphery of device 20 ends and the black aperture begins.

The encapsulation cover 700 is bonded to upper surfaces 423 of the spacer walls 421 in the interposer plate 410. Preferably the interposer plate 410 is first bonded to the encapsulation cover 700 to form an intermediate structure, and then bond the intermediate structure to the control layer 13. An anti-stiction coating and a getter material, as is known in the art, can be deposited on the device before the intermediate structure is bonded to the control layer 13. This bonding need not be hermetic, so it can easily be implemented by applying an organic sealant such as epoxy to the upper faces 423, followed by pressing the encapsulation cover 700 or the intermediate structure of cover 700 and interposer plate 410 against the structure to which it is bonded, as shown in FIG. 8. The device openings 420 are thus enclosed to form chambers 850 in which the micro devices 20 are encapsulated. The transparent encapsulation cover includes an upper surface 810. The openings 710 in the encapsulation cover 700 and the terminal openings 430 in the interposer plate 410 allow access to the I/O terminals 25.

Alternatively, the encapsulation cover 700 and interposer plate 410 can be formed monolithically by etching or molding.

Referring to FIG. 8, operable devices may be constructed without an interposer plate 410, provided that the distance required between the inner surface 820 of the encapsulation cover 700 and the surface of the micro device 20 is not too large. In that case, chambers 850 and terminal openings 430 can be created in an optically transparent encapsulation cover 700, even for a flat, optically transparent chamber 850 with a depth up to about 1000 um, directly to form a one-piece encapsulation cover 700. This option has only one sealing interface rather than two sealing interfaces.

One other alternative is to use the epoxy seal between encapsulation cover 700 and assembly 100 to provide the spacing for device 20. As is known in the art, inorganic or organic spheres of well defined size embedded in epoxy can define the spacing between encapsulation cover 700 and assembly 100.

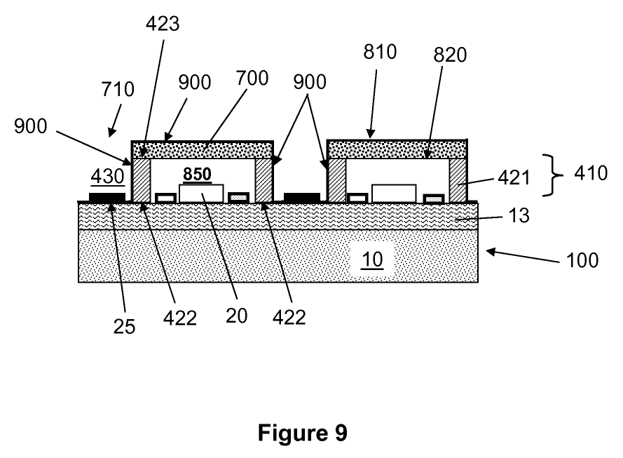

Referring to FIG. 9, a hermetic-sealing layer 900 of sealing material is next deposited on the external surfaces of the chambers 850 to provide hermetic sealing of the micro devices 20 on the assembly 100. The sealing material may be deposited using various deposition techniques that produce a conformal coating, such as atomic layer deposition (ALD), chemical vapor deposition (CVD), plasma enhanced CVD (PECVD), physical vapor deposition (PVD) or electroplating. Materials compatible with the conformal deposition can include Al₂O₃, SiO₂ and TiO₂ for ALD, Si₃N₄, C or SiO₂ for CVD, Si₃N₄, C or SiO₂ for PECVD, and Ag, Sn, Sb, Pt, Ni, Au and Cu for electroplating. The hermetic-sealing layer 900 fully covers the side surfaces of the spacer walls 421, the non-hermetic interfaces at the upper surfaces 423 and the base faces 422, thus hermetically sealing the chambers 850 and the micro devices 20 therein.

The hermetic-sealing layer 900 can be controlled to be rather thin, such as 1 to 100 nanometers. The thicker the layer 900, the better the hermeticity of the seal. However, a thinner layer is preferred for optical transparency. This layer may be deposited using ALD, which does not interfere with optical transmission through the transparent encapsulation cover 700. In some embodiments, the upper surfaces 810 and electrical pads 430 can be masked by a masking layer before the conformal isotropic deposition to allow a relatively thick and opaque layer to be deposited on the outer surfaces of the chamber 850 without affecting the transparency of the encapsulation cover 700. The hermetic-sealing layer 900 can be deposited to a thicker range of about 0.5 micron to 5 microns using techniques such as PECVD. If a mask layer is used, it is later removed to allow optical transmission through the transparent encapsulation cover 700 and to allow attachment of electrical interconnects.

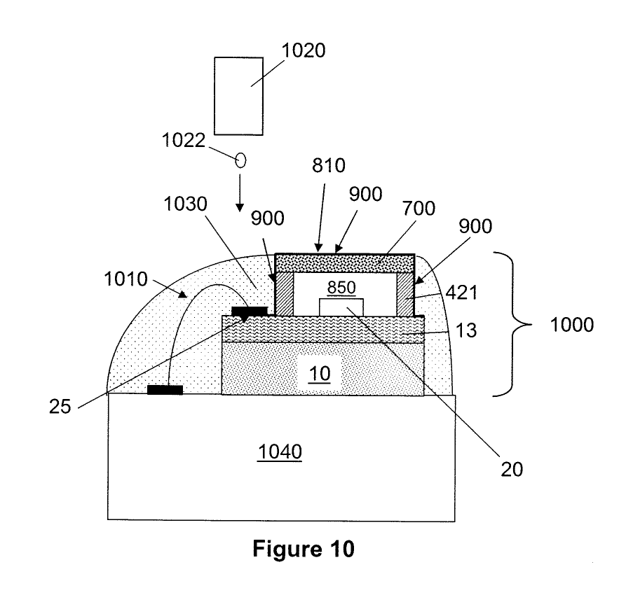

The hermetic-sealing layer 900 can provide hermeticity to the seal the chamber 850 and the micro device 20. The sealing of the chamber 850 can be accomplished by a combination of the hermetic-sealing layer 900, the bonding between the interposer plate 410 and the control layer 13, and additional bonding outside of the hermetic-sealing layer 900 as described relation to FIG. 10. These sealing measures in combination can enhance the overall hermeticity of the chamber 850.

An advantage of the disclosed hermetic sealing techniques is that hermetical sealing can be efficiently applied to a plurality of micro devices on a substrate such as a semiconductor wafer. The hermetic sealing is applied after the construction of the micro chambers that encapsulate the micro devices. The separation of the hermetic sealing step from the construction of the micro chambers allow much easier processing steps for building the micro chambers as compared to conventional systems.

Another advantage of the disclosed hermetic sealing techniques is that hermetic sealing can be applied to micro devices at a low temperature that does not affect the electric circuitry in the control layer 13 or the micromirror structure shown in FIG. 2B. For example, the hermetic-sealing layer can be deposited below 200° C., which is safe for CMOS circuitry and MEMS devices that use metal or metal alloys on a semiconductor substrate. Processing is generally done at as high a temperature as possible to produce a higher quality film, but not so high as to damage the structures.

Still referring to FIG. 10, the substrate 10, the control layer 13, the interposer plate 410, and the encapsulation cover 700 are next diced to separate the plurality of hermetically sealed micro devices 20 into a plurality of dies 1000, each containing at least one hermetically sealed micro device 20, as shown in FIG. 10. The device may then be bonded to a substrate 1040 which can be ceramic, plastic or a printed circuit board or flex circuit. A wire 1010 can be bonded to the terminals 25 to receive external electric signals for controlling the micro device 20.

Optionally, a sealing material 1022 can be disposed by a fluid dispenser 1020 to form a glob top 1030 of protective material over the terminal 25, which provides protection to the terminal 25. The glob top 1030 can also cover the hermetic-sealing layer 900 on the outer surface on the side of the chamber 850, which can provide further sealing to the chamber 850. The glob top 1030 can be applied to seal as many of the surfaces of the chamber 850 as are available. The glob top should not cover the top surface of the device so as not to interfere with its optical operation. In one embodiment, the hermetic coating described above may be carried out after the glob top has been applied.

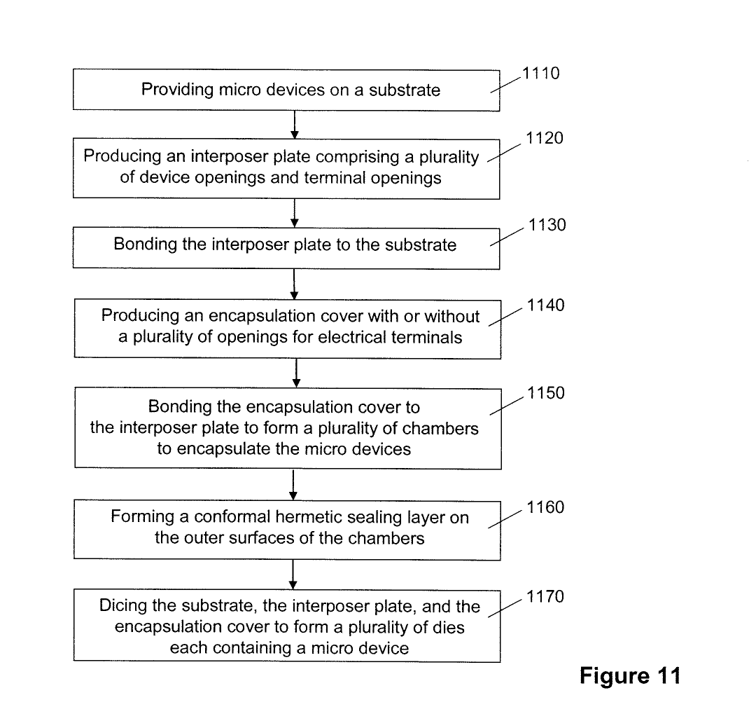

Referring to FIG. 11, a process for hermetic sealing micro devices can include one or more of the following steps. Micro devices are first provided preferably on a substrate by micro fabrication on the substrate or by surface mount techniques (step 1110). One or more electrical terminals can be disposed on the substrate and adjacent to each micro device for receiving electrical signals that control the respective micro devices. An interposer plate comprising a plurality of openings is produced (step 1120). The openings include device openings and terminal slots or openings that are positioned respectively in registration to the micro devices and the terminals. If desired, an interposer plate may next be bonded to the upper surface of the substrate (step 1130) or, alternatively, to the encapsulation layer. The micro devices and the terminals are respectively enclosed in the device openings and the terminal openings. An encapsulation cover comprising a plurality of openings is produced (step 1140). If desired, in one embodiment, openings in the encapsulation cover may be used to provide access to the electrical terminals on the substrate. Furthermore, if desired, an anti-stiction coating (a lubricant) may be dispensed into the cavities. Also, if desired, a moisture absorbing material (a getter) or other suitable getter (e.g., for oxygen) can be applied to an internal surface of the micro chambers before the micro chambers are enclosed so that moisture in the micro chambers can be reduced.

As discussed above, alternatively, the interposer plate may be bonded to the encapsulant glass first. Or the interposer may be made in one piece with the encapsulant glass, such as by molding or etching. In some embodiments, an interposer plate may not be used at all.

The encapsulation cover is next bonded to the upper surface of the interposer plate to form a plurality of micro chambers to encapsulate the micro devices (step 1150). A hermetic-sealing layer, such as a conformal hermetic-sealing layer, is next deposited on the outer surfaces of the micro chambers, such as by isotropic deposition, to hermetically seal the micro devices in the micro chambers (step 1160). The substrate, the interposer plate, and the encapsulation cover are next diced to separate the plurality of hermetically sealed micro devices into a plurality of dies each containing at least one hermetically sealed micro device (step 11170).

In another embodiment using adhesive material to bond the interposer plate to the upper surface, the adhesive material, such as epoxy, does not completely seal the chamber intentionally. After the wafers are bonded, an anti-stiction material is deposited in the wafer by vapor deposition. Only then is each microchamber completely sealed with a plug that may be made of epoxy or other adhesive material. Then the hermetic coating may be applied.

It is understood that the disclosed systems and methods are compatible with different techniques and materials in addition to the ones described above. The micro devices are not limited to the examples described above. Other suitable micro devices, by way of example and not limitation, include organic light emitting diode (OLED) and liquid crystal display (LCD) devices.

1. An encapsulated device, comprising:
a micro device on a substrate;
a micro chamber that encapsulates the micro device on the substrate, wherein the micro chamber is defined in part by one or more walls extending away from a surface of the substrate, one surface of a wall of the one or more walls being adjacent to the micro device and an opposite surface of the wall defining an outer surface of the micro chamber; and
a layer of inorganic sealing material that provides at least some degree of hermeticity fully covering the one or more outer surfaces of the micro chamber to seal the micro device in the micro chamber.

2. The encapsulated device of claim 1, wherein the layer of inorganic-sealing material is isotropically deposited using a technique selected from the group consisting of atomic layer deposition (ALD), chemical vapor deposition (CVD), plasma enhanced CVD (PECVD), physical vapor deposition (PVD) and electroplating.

3. The encapsulated device of claim 1, wherein the layer of inorganic-sealing material conforms to the one or more outer surfaces of the micro chamber.

4. The encapsulated device of claim 1, wherein the layer of inorganic-sealing material has a thickness smaller than 5 microns.

5. The encapsulated device of claim 4, wherein the layer of inorganic-sealing material has a thickness in a range between about .5micron and about 5 microns.

6. The encapsulated device of claim 4, wherein the layer of inorganic-sealing material has a thickness in a range between about 1 and about 100 nanometers.

7. The encapsulated device of claim 1, wherein the inorganic-sealing material comprises a material selected from the group consisting of Al₂O₃, SiO₂, TiO₂, Si₃N₄, SiO₂, C, Ni, Au, Cu, Pt, Sn, Sb, and Ag.

8. The encapsulated device of claim 1, wherein the micro chamber comprises:
an interposer plate bonded to an upper surface of the substrate, wherein the interposer plate includes an opening in which the micro device is positioned after the interposer plate is bonded to the upper surface of the substrate; and
an encapsulation cover bonded to the interposer plate, wherein the interposer plate and the encapsulation cover form the micro chamber to encapsulate the micro device.

9. The encapsulated device of claim 8, wherein the encapsulation cover is made of a transparent material.

10. The encapsulated device of claim 9, wherein the interposer plate is bonded to the substrate and the encapsulation cover is bonded to the interposer plate by an organic adhesive.

11. The encapsulated device of claim 10, wherein the substrate includes an electrical terminal on its upper surface in the vicinity of the micro device, and wherein the electrical terminal is configured to receive an electrical signal to control to the micro device.

12. The encapsulated device of claim 11, wherein the interposer plate includes a recess in which the electrical terminal is positioned after the interposer plate is bonded to the upper surface of the substrate.

13. A method for hermetically sealing a plurality of micro devices on a substrate to form the encapsulated device of claim 1, comprising:
constructing a plurality of non-hermetic micro chambers on the substrate to respectively encapsulate the plurality of micro devices; and
depositing a layer of inorganic-sealing material on the outer surfaces of the micro chambers to fully cover the outer surfaces and hermetically seal the micro devices within the micro chamber.

14. The method of claim 13, wherein the layer of inorganic-sealing material is deposited isotropically.

15. The method of claim 13, wherein the layer of inorganic-sealing material is deposited using a deposition technique selected from the group consisting of atomic layer deposition (ALD), chemical vapor deposition (CVD), plasma enhanced CVD (PECVD), physical vapor deposition (PVD) and electroplating.

16. The method of claim 13, wherein the step of constructing a plurality of non-hermetic micro chambers comprises:
bonding encapsulation covers respectively to a plurality of interposer plates to form micro chambers;
bonding the plurality of combined encapsulation covers and interposer plates to an upper surface of the substrate, wherein the interposer plate includes a device recess in which the micro device is positioned.

17. The method of claim 16, wherein the steps of bonding the interposer plates and the encapsulation covers comprise the application of a sealing material.

18. The method of claim 13, wherein the substrate includes an electrical terminal on an upper surface of the substrate in the vicinity of the micro device, wherein the electrical terminal is configured to receive an electrical signal to control to the micro device.

19. The method of claim 18, wherein the interposer plate includes a terminal recess in which the electrical terminal is positioned when the interposer plate is bonded to the upper surface of the substrate.

20. The method of claim 18, further comprising disposing a sealing material to cover the electrical terminal and at least a portion of the layer of inorganic-sealing material on the micro chamber.

21. The method of claim 13, wherein the layer of inorganic-sealing material conforms to the one or more outer surfaces of the micro chamber.

22. The method of claim 13 including the additional step of testing the micro devices on the substrate before depositing the layer of inorganic sealing material.

23. The method of claim 17 including the additional step of testing the micro devices on the substrate after application of the sealing material by sending a signal to the electrical terminal to control the micro device.

24. The method of claim 16 including the additional step of dispensing anti-stiction material on the micro devices before bonding the combined encapsulation covers and interposer plates to the upper surface of the substrate.
